(19) United States
(12) Patent Application Publication
(10) Pub. No.: US 2016/0322224 A1
(43) Pub. Date: Nov. 3, 2016

(54) PROCESSES FOR USING FLUX AGENTS TO FORM POLYCRYSTALLINE GROUP III-GROUP V COMPOUNDS FROM SINGLE SOURCE ORGANOMETALLIC PRECURSORS

(71) Applicant: Dow Global Technologies LLC, Midland, MI (US)

(72) Inventors: Robert J. WRIGHT, Sugar Land, TX (US); Anatoliy N. SOKOLOV, Midland, MI (US); George L. ATHENS, Freeland, MI (US); Peter N. NICKIAS, Midland, MI (US); James C. STEVENS, Richmond, TX (US); Liam L. SPENCER, Manvel, TX (US); Bruce B. GERHART, Midland, MI (US); Anna M. PICKENS, Midland, MI (US)

(21) Appl. No.: 15/107,710

(22) PCT Filed: Dec. 10, 2014
(86) PCT No.: PCT/US2014/069456

§ 371 Date: Jun. 23, 2016

Related U.S. Application Data
(60) Provisional application No. 61/921,840, filed on Dec. 30, 2013.

(51) Int. Cl. H01L 21/02; H01L 31/18; C07F 9/74; H01L 21/324; C09D 5/24; C07F 9/72

(52) U.S. Cl. CPC H01L 21/02546; C09D 5/24; C07F 9/72; C07F 9/743; H01L 21/02628; H01L 21/3245; H01L 21/02595; H01L 31/184

(57) ABSTRACT

The present invention provides methods for using single source organometallic precursors in the fabrication of polycrystalline Group III-Group V compounds, preferably semiconductor compounds. The present invention teaches how to select organometallic ligands in single-source precursors in order to control the stoichiometry of the corresponding Group III-Group V compounds derived from these precursors. The present invention further teaches how to anneal precursors in the presence of one or more flux agents in order to increase the crystalline grain size of polycrystalline Group III-Group V compounds derived from organometallic precursors. This helps to provide Group III-Group V semiconductors with better electronic properties. The flux layer also helps to control the stoichiometry of the Group III-Group V compounds.

### CROSS-REFERENCE TO RELATED APPLICATIONS

This application claims priority to U.S. Provisional Patent Application No. 61/921,840, filed Dec. 30, 2013, the entire contents of which are incorporated herein by reference in its entirety.

### FIELD OF THE INVENTION

The present invention relates to forming polycrystalline Group III-Group V compounds (e.g., polycrystalline gallium arsenide) from organometallic precursors. More particularly, the present invention relates to forming polycrystalline Group III-Group V pnictides (e.g., polycrystalline gallium arsenide) from organometallic precursors, wherein the precursors are annealed in the presence of one or more flux agents in order to provide polycrystalline Group III-Group V compounds with improved crystallinity and electronic characteristics.

### BACKGROUND OF THE INVENTION

Solar cells are microelectronic devices that convert solar radiation and other light into usable electrical energy. The energy conversion occurs as the result of the photovoltaic effect. Solar cells also are referred to as photovoltaic devices or cells. Other microelectronic devices include laser diodes, transistors, lasers, quantum hetero structures, liquid crystal displays, substrates for epitaxial growth of other semiconductors, semi-insulating crystals, mobile phones, satellite circuitry, aircraft circuitry, microprocessors, integrated circuits, sensors, detectors, optical windows, integrated circuits, power electronics, and the like.

Solar cells generally incorporate one or more semiconductor layers that help to convert light into electrical energy. These layers may have p-type, n-type, or intrinsic conductivity characteristics depending upon the role of the layer in the device. Other microelectronic devices also incorporate one or more semiconductor layers to help achieve desired electronic functions.

Polycrystalline semiconducting compounds formed from one or more Group III elements and one or more Group V pnictogens are one type of semiconductor material used in solar cells and other microelectronic devices. Gallium arsenide and corresponding alloys such as indium gallium arsenide are examples of Group III-Group V semiconductors.

Metal organic chemical vapor deposition (MOCVD) is one technique used to fabricate Group III/Group V semiconductors from suitable sources. For example, MOCVD processes have been used to fabricate polycrystalline gallium arsenide from sources such as Me₃Ga and AsH₃. The objective is that these sources react to form stoichiometric polycrystalline gallium arsenide (GaAs) in situ on the desired substrate with relatively large crystalline grain characteristics. This is an advantage because stoichiometric, polycrystalline Group III-Group V semiconductors generally have better electronic properties when the average crystalline grain size of the material is larger. Stoichiometric, polycrystalline gallium arsenide has a stoichiometry in which the atomic ratio of Ga to As is 1:1.

MOCVD processes have been used to prepare polycrystalline GaAs that is stoichiometric. MOCVD processes also have been used to prepare polycrystalline GaAs with relatively large crystalline grains. Unfortunately, MOCVD provides large grains of stoichiometric GaAs at the expense of Ga and As utilization. This is a significant problem. Only about 30% to 50% of the Ga (e.g, in the form of Me₃Ga) and only 5% to about 20% of the As (e.g., in the form of AsH₃) is incorporated into the GaAs. Therefore, the MOCVD process is wasteful, and Ga and As materials are very expensive. This expense in combination with inefficient utilization is one of the main reasons that GaAs solar cells are not cost competitive with other technologies. It is very desirable that Group III/Group V semiconductors such as GaAs be made more efficiently.

Fabricating Group III-Group V semiconductors such as gallium arsenide from single source organometallic precursors offers substantial potential to improve the efficiency by which a material such as GaAs is formed from precursor material(s). A single source organometallic precursor comprises pre-associated Group III-Group V bonds, and one or more of H and/or one or more organic ligands are attached to each of the Group III and Group V elements, respectively. Ideally, annealing the precursors causes the organic ligands to be released, leaving Group III-Group V compounds with a stoichiometry that hopefully corresponds strongly to the stoichiometry of the Group III and Group V elements in the precursor.

Annealing further hopefully provides a polycrystalline product with large crystalline grains to promote good electronic properties. The strategy of using single source organometallic precursors is attractive because it offers the potential to use the single source precursors at much higher efficiency than MOCVD processes use source materials. PCT Patent Pub. No. WO 2012/044978 describes forming polycrystalline gallium arsenide from organometallic gallium arsenide precursors. In contrast to chemical vapor phase processes such as MOCVD, single source organometallic precursors have been applied to substrates not only in the vapor phase but also by using solution deposition and other liquid phase processes.

Although forming Group III-Group V semiconductors from single source organometallic precursors offers many advantages, several challenges remain. As one significant challenge, our XRD analysis of GaAs fabricated from previously known methods using single source organometallic precursors indicates that the resultant GaAs has relatively small crystalline grains and might not even be fully polycrystalline. This is particularly problematic when those precursors are coated onto a substrate in the liquid phase using solution deposition or the like. The small crystalline grains undermines electronic performance in many applications.

As another challenge, our EDS analysis of GaAs fabricated from previously known methods using single source organometallic precursors indicates that the resultant GaAs is not stoichiometric and may have a Ga and As content that differs substantially from that of the single source precursor. The stoichiometric deficiency is particularly problematic when those precursors are coated onto a substrate in the liquid phase using solution deposition or the like. For example, as noted above, stoichiometric polycrystalline gallium arsenide has a stoichiometry in which the atomic ratio of Ga to As is 1:1. A corresponding single source organometallic precursor also may have Ga and As content at an atomic ratio of Ga to As of 1:1. However, annealing the precursor may tend to produce polycrystalline gallium arsenide that is significantly deficient with respect to gallium and/or arsenic. This is due at least in part to the relative volatilities of organogallium and organoarsenic species. In some uses, this deficiency is problematic. Loss of gallium and/or arsenic reduces the efficiency by which the single source precursor is used to form the desired polycrystalline GaAs product.

Therefore, there is a strong need for improved methods for using single source organometallic precursors in the fabrication of polycrystalline Group III-Group V compounds.

### SUMMARY OF THE INVENTION

The present invention provides improved methods for using single source organometallic precursors in the fabrication of polycrystalline Group III-Group V compounds, preferably semiconductor compounds. The present invention teaches how to select organometallic ligands in single-source precursors in order to control the stoichiometry of the corresponding Group III-Group V compounds derived from these precursors. The present invention further teaches how to anneal precursors in the presence of one or more flux agents in order to increase the crystalline grain size of polycrystalline Group III-Group V compounds derived from organometallic precursors. This helps to provide Group III-Group V semiconductors with better electronic properties. It is also believed that the flux layer may also function to control the stoichiometry of the Group III-Group V compounds.

In one aspect, the present invention provides a method of making polycrystalline gallium arsenide, comprising the steps of:
a) providing a single source organometallic precursor comprising at least one Group III-Group V bond;
b) using the precursor to form a precursor film comprising at least the single source organometallic precursor; and
c) annealing the precursor film in the presence of a liquid phase in physical contact with at least a portion of the precursor film during at least a portion of the annealing, wherein the annealing occurs under conditions effective to convert at least a portion of the single source organometallic precursor into a polycrystalline Group III-Group V compound.

In another aspect, the present invention provides a Group III-Group V precursor system, comprising:
a) an organometallic precursor film comprising at least one single source precursor comprising a Group III-Group V bond; and
b) a flux layer in physical contact with and at least partially covering the precursor film, wherein the flux layer comprises at least one constituent that has a boiling point greater than 650° C. at 1 atm of pressure and wherein the constituent exists in a liquid phase in contact with the organometallic precursor film at a temperature in the range from 400° C. to 650° C. at 1 atm of pressure.

The system is useful for preparing polycrystalline Group III-Group V compounds using, for example, annealing techniques to accomplish the conversion. The reference of 1 atm of pressure does not require that the actual annealing occur at the reference pressure, but that the phase characteristics are determined at such reference pressure. Often, the annealing occurs in the temperature range from 400° C. to 650° C. Annealing may occur at a variety of pressures, including reduced pressure, ambient pressure, and/or elevated pressure.

### BRIEF DESCRIPTION OF THE DRAWINGS

FIG. 1 is a schematic illustration of a reaction scheme in which a preferred gallium arsenide organometallic precursor is converted into stoichiometric gallium arsenide.

FIG. 2 is an XRD plot showing the impact of addition of Bi flux on the crystallization of tBu(H)AsGaEt₂.

FIG. 3 is an XRD plot showing the impact of addition of Ga flux on the crystallization of (tBu(H)AsGaEt₂)ₙ.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather a purpose of the embodiments chosen and described is so that the appreciation and understanding by others skilled in the art of the principles and practices of the present invention can be facilitated.

The present invention provides methods of making polycrystalline Group III/V compounds. A Group III/V compound is a compound comprising at least one Group III element (also known as Group 13 elements and as the triels) bonded to at least one Group V element (also known as Group 15 elements and as pnictogens) Group III elements include one or more of boron (B), aluminum (Al), gallium (Ga), indium (In), and thallium (Tl). Gallium is preferred. Group V elements include one or more of nitrogen (N), phosphorus (P), arsenic (As), antimony (Sb), and bismuth (Bi). Arsenic is preferred. Group V elements (also known as pnictogens or Group 15 elements) include one or more of nitrogen (N), phosphorus (P), arsenic (As), antimony (Sb), and bismuth (Bi). Arsenic and phosphorus are preferred. Arsenic is more preferred.

Examples of Group III/V semiconductor compounds include gallium arsenide, gallium nitride, indium gallium arsenide, indium gallium nitride, gallium phosphide, indium gallium phosphide, gallium arsenide phosphide, gallium nitride phosphide, indium gallium arsenide phosphide, indium gallium nitride phosphide, gallium phosphide, indium gallium phosphide, gallium arsenide, gallium nitride arsenide, indium gallium arsenide, indium gallium nitride arsenide, gallium phosphide arsenide, indium gallium phosphide arsenide, combinations of these, and the like.

In these exemplary semiconductor compounds, indium (In) is an alloy constituent with gallium. Other metals also may be used as alloy constituents either in place of or in addition to Indium. Examples of such other metals include one or more of Al, Zn, Tl, Pb, Mg, Cd, Hg, Mn, Ag, Cu, Au, Sn, Ge, Co, Ni, Y, Zr, Nb, Mo, Te, Ru, Rh, Pd, La, Hf, Ta, W, and the like.

Group III/V semiconductors may be p-type, n-type, or intrinsic in terms of conductivity. In many embodiments, the conductivity or mobility characteristics of a Group III/V semiconductor can be adjusted by incorporating one or more suitable dopants into the Group III/V material. In some embodiments, the dopants that may be doped into the GaAs layer include one or more of Al, Zn, Tl, Sn, Pb, Mg, Cd, Hg, Mn, Ag, Cu, Au, Co, Ni, Y, Zr, Nb, Mo, Te, Ru, Rh, Pd, La, Hf, Ta, W, Ge, In, Si, Se, S, C, B, F, H, Br, Ca, and the like. Some of these elements alternatively may be used as alloy constituents rather than dopants. Dopant functionality may be distinguished from alloy functionality generally by the amount of a material incorporated into the Group III/V semiconductor. A metal species is alloyable in a resultant alloy if the alloy includes at from 0.8 to 99.2 atomic percent, preferably from 1 to 99 atomic percent of that metal based on the total metal content of the alloy. Alloyable species are distinguished from dopants, which are incorporated into semiconductor films or the like at substantially lower concentrations, e.g., concentrations in the range of 1×10²⁰ atom/cm³ to 1×10¹⁵ atom/cm³ or even less. For example, in a p-type doped GaAs layer, the p-type dopants may be doped in the GaAs layer with a dopant concentration between about 1×10¹⁷ atom/cm³ and about 1×10¹⁹ atom/cm³. In another example, in a n-type doped GaAs layer, the n-type dopants may be doped in the GaAs layer with a dopant concentration between about 1×10¹⁸ atom/cm³ and about 1×10²⁰ atom/cm³.

The principles of the present invention can be used to help improve the crystalline structure, and hence the electronic properties, of a wide range of Group III/V semiconductors. The principles of the present invention are particularly useful for making and improving the crystalline structure of stoichiometric and substantially stoichiometric Group III/V semiconductors.

A stoichiometric Group III/V compound is a semiconductor in which the atomic ratio of metal atoms (including Group III metals and other alloyed metals, if any) to pnictogen atoms is 1:1. For example, an illustrative stoichiometric Group III/V compound incorporating Gallium and Arsenic may be represented by the general Formula A:

MₓGa_{y}AsₙP^{N}ₘ

wherein M is one or more metals other than Ga; P^{N} is one or more pnictogens other than As; x+y=1; n+m=1, x is 0 to 0.3; y is 0.7 to 1.0; n is 0.7 to 1.0 and m is 0 to 0.3. In a stoichiometric Group III/V semiconductor, the ratio of (x+y) to (n+m) is 1.0:1.0. In a substantially stoichiometric Group III/V semiconductor, the ratio of (x+y) to (n+m) is in the range from 0.9:1.1 to 1.1:0.9, preferably 0.95:1.05 to 1.05:0.95.

Group III/V semiconductors may be used in a wide range of microelectronic applications. These applications include laser diodes, solar cells, transistors, lasers, quantum heterostructures, liquid crystal displays, substrates for epitaxial growth of other semiconductors, semi-insulating crystals, mobile phones, satellite circuitry, aircraft circuitry, microprocessors, integrated circuits, sensors, detectors, diodes, optical systems, integrated circuits, power electronics, and the like. Solar cell embodiments and the use of gallium arsenide precursors to make these solar cells have been described in PCT Patent Publication WO 2012/044978, the entirety of which is incorporated herein by reference for all purposes.

An illustrative process will now be described by which the principles of the present invention are used to help improve the crystalline characteristics of Group III-V compounds, preferably semiconductor compounds. The process is useful when such compounds are derived from single source organometallic precursor(s) via annealing the precursor(s) under conditions effective to convert the precursor(s) into a polycrystalline Group III/V compound. In an initial step, a single source organometallic precursor is provided. The precursor comprises at least one Group III-Group V bond. A Ga—As bond is an example of such a bond. Where an alloy is a desired product, one or more other metals may be incorporated into the precursor or into an admixture in combination with the precursor. Alternatively, other alloy constituents may be co-introduced with the single source precursor from independent source(s) before, during, or after formation of the precursor film, as described below, or even after the Group III/V semiconductor is formed.

An organometallic precursor includes at least one H and/or at least one organic group attached to at least one Group III element of the precursor and at least one H and/or at least one organic group attached to at least one Group V element constituent of the precursor. H and organic groups that are attached to the metal and/or pnictogen shall be referred to herein as ligands, also denoted by the symbol R¹ to denote ligands on a pnictogen such as As and R² (or preferred embodiments of R² denoted as R³ ligands as described further below) to denote ligands on a Group III element such as Ga. A ligand may be attached to the metal and/or pnictogen by a covalent bond, a coordination bond, or other associative bond. The organometallic precursors also are referred to herein as complexes regardless of the type of bond(s) or other association between the ligands and the metal and/or pnictogen. An organic ligand may be attached to a Group III and/or Group V atom at more than one attachment site.

As used herein, the term “organic” refers to a moiety that includes at least one carbon atom and at least one atom other than carbon. Preferred organic ligands include 2 to 20 carbon atoms, preferably 2 to 8 carbon atoms, even more preferably 2 to 4 carbon atoms. Organic ligands may be aliphatic or aromatic. Organic ligands may be saturated or unsaturated. Organic ligands may be linear, cyclic, or branched. Organic ligands may include one or more heteroatoms such as Si, N, O, P, and/or S.

A wide variety of ligands R¹ and R² are suitable in the practice of the present invention. Examples of R¹ and R² independently include H; hydrocarbyls such as alkyl, alkenyl, alkynyl, phenyl, and benzyl; haloalkyl in which the halo atom is at least one of F, Cl Br, and I; groups containing nitrogen such as one or more of carboxamide, primary amine, secondary amine, tertiary amine, primary ketimine, secondary ketimine, primary aldimine, secondary aldimine, imide, azide, azo, cyanate, isocyanate, nitrate, nitrile, nitrosoxy, nitro, nitroso, and pyridyl; and/or groups containing phosphorous such as one or more of phosphino, phosphoric acid, phosphate, and phosphodiester. Examples of alkyl ligands include methyl, ethyl, propyl, isopropyl, butyl, t-butyl, i-butyl, pentyl, cyclopropyl, cyclobutyl, cyclopentyl, combinations of these, and the like. Examples of other ligands are described in PCT Patent Publication WO 2012/044978A2.

Single source precursors desirably include a ratio of Group III to Group V atoms that matches the desired stoichiometry of the compound to be formed. For example, to form stoichiometric gallium arsenide in which the atomic ratio of gallium to arsenide is 1:1, it is desirable to use a single source precursor comprising pre-associated Ga—As bonds for which the atomic ratio of gallium to arsenide is 1:1. It is desirable to preserve the Ga—As bonds as the precursor is converted to the semiconductor in order to preserve the stoichiometry. However, if the conversion process causes undue amounts of decomposition of the Ga—As bonds, the semiconductor product will tend to have a different GaAs content than the precursor. The divergence from the desired stoichiometry tends to increase as more of the Ga—As bonds in the precursor decompose.

The bond energies between ligands and the triels(s) and pnictogen(s) in a precursor are important factors that impact the stoichiometry of resultant compound(s) derived from the precursor(s). For example, it is desirable that the ligands on the Ga and As tend to decompose and detach from the Ga and As more readily than the Ga—As bond decomposes under the conversion conditions. To achieve this, the bonding energy between a ligand and either Ga or As, as the case may be, is configured to be weaker than the bonding energy comprising the Ga—As bond. By this configuration, annealing the precursor more readily breaks the ligand bonds than the Ga—As bond. This favors formation of stoichiometric or substantially stoichiometric gallium arsenide. Because the ligands are more easily removed, evaporated, or pyrolyzed during conversion, a GaAs layer with minimum impurities or contamination may be obtained and formed on a substrate surface. Subject to a preferred condition that at least one ligand on As is H for reasons discussed below, selecting Ga ligands with weak bonds to Ga is important, as the gallium ligands have been observed to have more of an impact on the resultant stoichiometry than the nature of the non-H ligand(s) on the As. This was demonstrated in experiments in which single source precursors comprising Ga-ethyl (Et) bonds allowed the formation of substantially stoichiometric GaAs, whereas using precursors comprising stronger Ga-methyl (Me) bonds provided compounds that were much less stoichiometric.

The bonding dissociation energy between a ligand and Ga in kcal/mol is calculated with the M06 level of DFT theory and a 6-31g*(5d) basis set for the homoleptic species Ga(R²)₃, wherein R² is the gallium ligand under evaluation. This level of theory has been previously used, for instance, in Angew. Chem. 2012, 124(41), 10536-10539. The bond dissociation energy of the Ga—C bond, wherein the C atom is a methyl substituent, is 79.4 kcal/mol. Annealing precursors containing one or more methyl ligands on Ga has been observed to provide GaAs that is substantially arsenic deficient as measured by energy dispersive spectroscopy. This indicates that the Ga—C bond dissociation energy in a Ga—CH₃ moiety is high enough that, rather than decomposing the methyl to evolve methane upon annealing, substantial decomposition of the Ga—As bond occurs instead.

In contrast, the Ga—C bond dissociation energy in a Ga—CH₂CH₃ moiety is much lower at 73.6 kcal/mol. Annealing precursors containing ethyl ligands on Ga has been observed by us to more easily provide stoichiometric GaAs, with the evolution of ethane. This indicates that the Ga—C bond dissociation energy in a Ga—CH₂CH₃ moiety is weak enough to favor decomposition of the ethyl while more favorably preserving the Ga—As bond in precursors that contain As—H bonds. As another example, the Ga—C bond dissociation energy between —CH₂Ph (wherein Ph is phenyl, —C₆H₅) and Ga is even lower at 65.6 kcal/mol, indicating that —CH₂Ph also is a suitable ligand on gallium in these precursors when stoichiometric and substantially stoichiometric gallium arsenide is a desired product, wherein toluene evolves as a leaving group.

Calculated bond dissociation energies of three ligands (Me is methyl as a ligand and methane on its own; Et is ethyl as a ligand and ethane on its own; the Ph in —CH₂Ph is phenyl —C₆H₅, and tBu is t-butyl) with respect to Ga are summarized in the following table:

| | Bond Dissociation |
|---|---|
| Dissociation reaction | Energy (BDE), kcal/mol |
| Me₃Ga -> Me + Me₂Ga | 79.4 |
| Et₃Ga -> Et + Et₂Ga | 73.6 |
| Ga(CH₂Ph)₃ -> CH₃Ph + Ga(CH₂PH)₂ | 65.7 |
| Ga(tBu)₃ -> tBu + Ga(tBu)₂ | 61.8 |

In addition to bond dissociation energy between Ga and ligands being a factor that can impact the stoichiometry of the Group III/Group V product, the presence or absence of H as a ligand on arsenic is another factor that impacts the stoichiometry when As includes two or more ligands. Specifically, when arsenic ligands include at least one H and at least one organic ligand, formation of stoichiometric and substantially stoichiometric gallium arsenide is favored. Gallium arsenide was arsenic deficient when formed from precursors without hydride functionality on the arsenic. In contrast, stoichiometric gallium arsenide was formed when the arsenic included hydride and organic functionality and the gallium ligands had bond dissociation energies weaker than that associated with methyl ligands.

For example, in some modes of practice (e.g., when making solar cells incorporating gallium arsenide), it is desirable to form stoichiometric or substantially stoichiometric gallium arsenide. In these modes of practice, it is desirable to avoid using methyl ligands or other ligands on Ga having a Ga—C bond dissociation energy with respect to Ga that is 79 kcal/mol or higher. Instead, it is more desirable to use preferred gallium ligands R³ that have a Ga—C bond dissociation energy with respect to Ga that is less than 79 kcal/mol, preferably less than 77 kcal/mol, more preferably less than 75 kcal/mol as calculated using the 6-31g*(5d) basis set. More preferred embodiments of gallium ligands R² are denoted as ligands R³ comprise 2 to 10 carbon atoms, preferably 2 to 8 carbon atoms, more preferably 2 to 4 carbon atoms. In even more preferred modes of practice to form stoichiometric or substantially stoichiometric gallium arsenide, preferred gallium ligands R³ include ethyl, propyl, isopropyl and/or t-butyl as ligands on Ga and at least one H and at least one of ethyl, propyl, isopropyl and/or t-butyl on As.

In other modes of practice, the stoichiometry of the resultant gallium arsenide is less critical. In these modes of practice, restricting ligands based on bond dissociation energy may still be practiced but also is less critical. Using one or more methyl ligands or the like on Ga and/or As would be suitable, and representative embodiments need not include hydride functionality on As to provide optimum products.

To form stoichiometric or substantially stoichiometric gallium arsenide preferred gallium arsenide precursors have Formula B

[R¹HAs—GaR³₂]ₚ

and/or Formula C:

[R¹As—GaR³]_{q}

wherein each R¹ independently is H or an organic moiety as defined above, and each R³ independently is an organic moiety as defined above; p is 1 to 6, preferably 2 to 3; and q is 1 to 8. Preferred As ligands R¹ include ethyl and t-butyl.

A precursor in which p or q is 1 is referred to as a monomer. Exemplary monomer embodiments of compounds according to Formula B and C include:

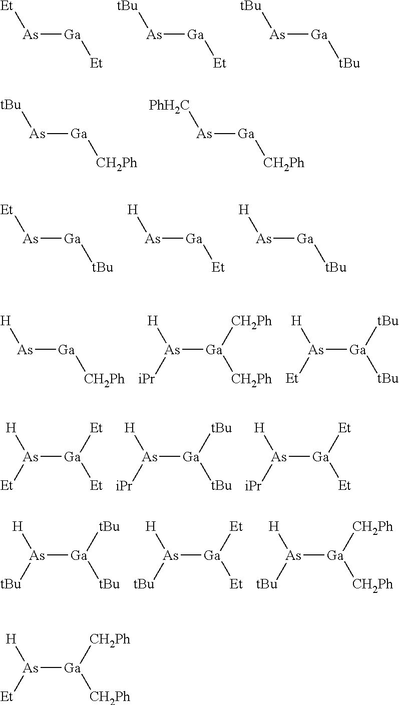

A precursor in which p or q is 2 is referred to as a dimer. Exemplary dimer embodiments of compounds according to Formula B and C include

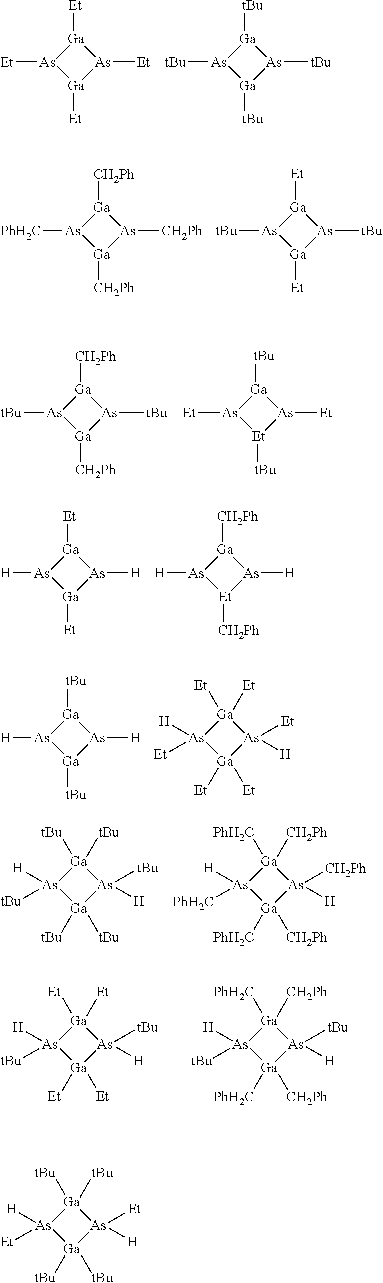

A precursor in which p or q is 3 is referred to as a trimer. Exemplary trimer embodiments of compounds according to Formula B and C include

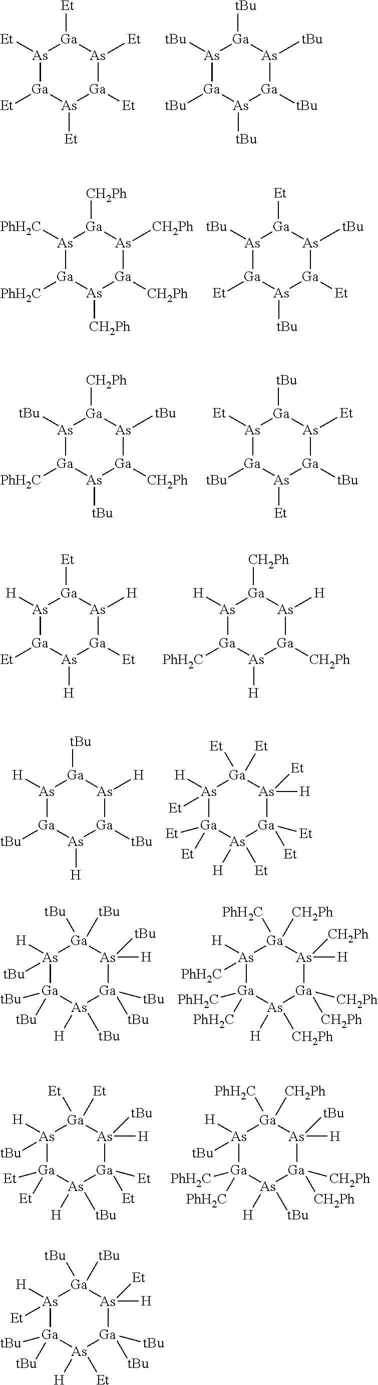

Trimer embodiments of gallium arsenide precursors according to Formula B are preferred. Dimer or trimer embodiments of gallium arsenide precursors according to Formula C are preferred. Mixtures of precursors according to Formula B and/or C also may be used. In these, the precursors may be physically intermixed. The combination of precursors also may exist as cluster species in which complexes of multiple precursor molecules of the same or different type form, a larger cluster through covalent bonds, coordinate bonds, or other association. Such cluster species may result upon mild heating, but also can form as a solution or admixture of the precursor(s) ages. Examples of mixed and/or cluster species include one or more of

{[tBu(H)AsGaEt₂]ₘ(tBuAsGaEt)ₙ};

{[tBu(H)AsGa(CH₂Ph)]ₘ[tBuAsGa(CH₂Ph)]ₙ};

{[tBu(H)AsGa(tBu₂)]ₘ[tBuAsGa(tBu)]ₙ};

{[Et(H)AsGaEt₂]ₘ[(EtAsGaEt)]ₙ};

{[Et(H)AsGa(CH₂Ph)]ₘ[EtAsGa(CH₂Ph)]ₙ};

{[Et(H)AsGa(tBu₂)]ₘ[EtAsGa(tBu)]ₙ};

{[(CH₂Ph)(H)AsGaEt₂]ₘ[(CH₂Ph)AsGaEt)]ₙ};

{[(CH₂Ph)(H)AsGa(tBu))]ₘ[(CH₂Ph)AsGa(tBu)]ₙ};

{[(CH₂Ph)(H)AsGa(CH₂Ph)M(CH₂Ph)AsGa(CH₂Ph)]ₙ};

{[tBu(H)AsGaEt₂]ₘ(tBuAsGatBu)ₙ};

{[tBu(H)AsGatBu₂]ₘ(tBuAsGaEt)ₙ};

{[tBu(H)AsGatBu₂]ₘ(tBuAsGatBu)ₙ};

{[tBu(H)AsGaEt₂]ₘ(tBuAsGa(CH₂Ph))ₙ};

{[tBu(H)AsGa(CH₂Ph)₂]ₘ(tBuAsGaEt)ₙ};

{[tBu(H)AsGa(CH₂Ph)₂]ₘ(tBuAsGa(CH₂Ph))ₙ};

wherein each m and n independently is 1 to 10, preferably 2 to 3.

According to one method of preparing organometallic precursors in preferred modes of practice, an organometallic Group V dihydride comprising at least one R¹ substituent is provided. AsR¹H₂ is an example of such compounds. Preferred embodiments of R¹ are ethyl (Et) and t-butyl (tBu). A solvent is not required at this stage. However, in some modes of practice, the Group V dihydride is diluted with a suitable solvent such as hexane and/or toluene. A suitable concentration is 0.1M to 2M. In one embodiment, a concentration of 1 M was suitable. An organometallic Group III compound is added to the admixture. GaR²₃ and/or GaR³₃ are examples of such compounds, wherein R² and R³ are as defined above. Enough of the Group III compound is added so that the molar ratio of Group III atoms to Group V atoms in the admixture is at least 1:1, and preferably is 1:1. Using a stoichiometric excess of the Group III compound is not needed, although an excess could be used if desired. Preferred embodiments of R² and the more preferred R³ ligands are ethyl (Et) and t-butyl (tBu).

The admixture is then heated to a desired temperature and held at the temperature for a suitable time period to allow the reactants to form a precursor with pre-associated Group III-Group V bonds. In one mode of practice, the temperature is 70° C. to 80° C. Preferably, the admixture is heated in refluxing solvent. In the case of hexane, this is about 80° C. In other embodiments, e.g., those in which the ligand bonds are weaker, the reaction may be carried out at a lower temperature such as room temperature or even colder. For example, PCT Pat. Pub. No. 2012/044978 describes forming precursors at a temperature in the range from −90° C. to −40° C. In many suitable embodiments, the reaction is allowed to proceed for a time period in the range from 30 minutes to 48 hours, preferably 4 hours to 30 hours. Some reactants may be volatile under the reaction conditions. If this is the case, the reaction can occur in a closed system. Volatile by-products may be removed from the closed vessel as the reaction proceeds and/or afterwards.

In a representative reaction scheme, tBuAsH₂ (tBu is t-butyl) is reacted with GaEt₃ to form an organometallic precursor with a pre-associated As—Ga bond. H and tBu are ligands on As, while first and second ethyl ligands are on Ga. The corresponding monomer, dimer, and trimer have the following structures, although NMR analysis indicates most of the product is in trimer form:

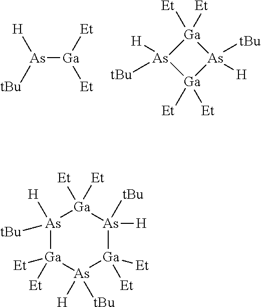

The processes of the present invention further involve using one or more organometallic precursors to form a film on a suitable substrate. A wide range of different substrates may be used. The choice of a suitable substrate generally depends to a large degree upon the kind of device being fabricated and the manner by which the device is being made. In many illustrative embodiments, suitable substrates can be formed from one or more polymers, one or more metallic materials (including metals, metal alloys, and intermetallic compositions), oxides, nitrides, carbides, semiconductors, glass, quartz, alumina, and/or other suitable materials.

To facilitate forming films using ingredients comprising one or more organometallic precursors, many modes of practice involve dissolving or dispersing one or more organic precursors in a suitable liquid carrier to form precursor coating admixtures. Solutions are preferred. Examples of liquid carriers include toluene, hexane, xylene(s), combinations of these, and the like. Some precursors used in the practice of the present invention may be sensitive to oxidation and/or moisture. Accordingly, it may be desirable to de-oxygenate the liquid carrier and/or dry the liquid carrier to remove water.

The concentration of precursor in the liquid carrier can vary over a wide range. Selecting a suitable concentration will depend upon factors including the type(s) of precursor(s), the nature of the substrate, the type of device being fabricated, and the techniques to be used to form the corresponding precursor film(s). In many suitable modes of practice, the concentration of the total amount of precursor(s) in the liquid carrier is in the range from 0.1 M to 4 M, preferably 0.3 M to 2 M, more preferably 0.5 M to 1.5 M. In one mode of practice, using a precursor according to Formula B at 8 M in toluene was found to be suitable.

In addition to the Group III/V organometallic precursor(s) and liquid carrier, the precursor coating admixtures optionally may include one or more other ingredients. Examples include one or more flux agents (described further below), one or more dopants, alloy constituents or precursors thereof, combinations of these and the like. As an alternative to or in addition to including flux agents, dopants and alloy constituents in the precursor coating admixture, dopants and/or alloy constituents may be co-deposited from independent source(s) onto the substrate before, during, or after the precursor admixture is deposited. As another option, dopants and/or alloys can be introduced before, during, or after formation of the polycrystalline Group III/Group V product (e.g., stoichiometric polycrystalline gallium arsenide) formed from the organometallic precursor(s).

The precursor coating admixtures are delivered, injected, sprayed, or otherwise coated or deposited onto the substrate to form precursor films with high uniformity and good film quality. Coating from precursor admixtures is reliable and repeatable. A wide variety of coating techniques may be used to form the precursor films. Examples include physical vapor deposition or other vapor phase coating process, spraying, printing, spin coating, meniscus coating, dip coating, electroplating, drop-casting, gravure coating, slot-die coating, Meyer bar and roller coating, combinations of these and the like.

For example, in one mode of practice, one or more substrate(s) are placed in a suitable processing chamber. The substrates may be stationary or may be rotated on a supporting turntable to promote more uniform deposition. The precursor coating admixture optionally may be atomized using a suitable technique such as by using an aerosol generator or by impacting stream(s) of the admixture with atomizing streams of an atomizing gas such as N₂, Ar, or the like. The atomized material may be sprayed, coated, or otherwise directly deposited onto the substrate. Alternatively, the atomized material may be converted into a vapor to accomplish vapor phase deposition on the substrate. A carrier gas may be used to help transport the atomized material. After the deposition, the coated material is allowed or caused to dry. A precursor film is thus formed on the substrate. To avoid oxidation or other undesired degradation of the precursor material, the film forming and further processing to make the desired pnictide product(s) desirably occurs in a protected atmosphere.

The film forming may occur at a wide range of temperatures and pressures effective to form the film precursor. In exemplary modes of practice, this may occur at ambient pressure, at elevated pressure, or at a reduced pressure. Forming the film at ambient pressure or a moderate vacuum is convenient and cost effective. Exemplary film forming temperature may be in a range from −25° C. to 300° C., preferably 15° C. to 200° C., more preferably 15° C. to 25° C.

The dried precursor film may have a thickness selected within a wide range. The thickness will depend upon factors including the nature of the device being fabricated and the role of the resultant polycrystalline pnictide in the resultant device. In many modes of practice, the precursor film is formed under conditions such that the resultant film has a thickness in the range from 10 nm to 2 μm, preferably 1 μm to 2 μm. Multiple precursor films may be deposited in series in order to achieve a desired overall film thickness. For example, a precursor film and corresponding flux layer may be deposited and then the stack is annealed. This first deposition/annealing stage may then be followed by at least one additional deposition/anneal stage in the presence of corresponding flux layers to build up such a multilayer structure. In many modes of practice, the flux layer used to anneal each of the precursor films optionally may be at least partially removed prior to further deposition/annealing stages.

An important aspect of the present invention is that at least a portion of the annealing occurs in the presence of a liquid phase in contact with at least a portion of the precursor film. In some embodiments, the liquid phase is a liquid layer that is present on the precursor film during the annealing. An important advantage of annealing the precursor film in the presence of such a liquid layer is that the crystalline grain size of the resultant polycrystalline pnictide is improved for better electronic performance. In one experiment, it was shown that annealing in the presence of the liquid layer increases the crystalline grain size of a GaAs pnictide as determined by X-ray diffraction methods using the Scherrer equation. The use of flux agents allowed crystalline grain size to be increased from about 12 nm to 85 nm in a representative mode of practice and from 12 nm to 30 nm in another representative mode of practice. The liquid phase desirably covers at least a portion and preferably substantially all of the precursor film.

Without wishing to be bound by theory, we hypothesize that the advantages of annealing in the presence of the liquid phase relates to reactant and product mobilities. In the absence of the liquid phase, annealing an organometallic precursor comprising a pre-associated Group III-Group V bond leads to conversion of the precursor into a polycrystalline form. During crystallization, a lack of reactant and product mobility within the film is believed to limit the crystalline grain size. We have found, however, that annealing the precursor in contact with a liquid phase at the annealing temperature(s) allows larger crystalline grains to form. It is believed that the liquid phase enhances reactant and product mobility to help provide this advantage and thereby functions as a flux at least with respect to mobility. Because the liquid phase enhances reactant and product mobility, the one or more constituents of the liquid phase are referred to herein as flux agents. It is also believed that the liquid phase layer helps to maintain the stoichiometry of the Group III-Group V constituents as the precursor is converted into polycrystalline material.

Generally, suitable flux agents have one or more desired properties. First, at least a portion of the flux agent should exist as a liquid phase under the annealing conditions. In many embodiments, annealing desirably occurs in a temperature range from 350° C. to 650° C., preferably 400° C. to 600° C. Accordingly, representative flux agents have a boiling point higher than the annealing conditions and have a melting point below the annealing conditions such that the agent is a liquid in at least a portion of these temperature ranges. Suitable flux agents may exist as liquids or solids at temperatures below the annealing conditions. For example, some flux agents may be solid at room temperature and do not become liquids until heated to elevated temperatures well above room temperature. It is also desirable that a flux agent is substantially inert with respect to the precursor constituents and has little if any tendency to be incorporated into the precursor film or crystallized product as inclusions or other contamination, or to react with the Group III, Group V, dopants (if any), alloyed metal, or other film constituents to form undue amounts of additional, undesired phases.

Exemplary embodiments of flux agents useful for making polycrystalline pnictides, preferably polycrystalline gallium arsenide, include one or more metals, metal alloys, or intermetallic compositions that have a melting point below 400° C., preferably below 300° C. and a boiling point greater than 650° C., preferably greater than 850° C., more preferably greater than 1000° C., even more preferably greater than 1500° C. In the practice of the present invention, boiling points and melting points are determined at 1 atmosphere of pressure. Examples of flux agents include Bi, Ga, and combinations of these. Bismuth has a melting point of 271° C. and a boiling point of 1564° C. Gallium has a melting point of 29.8° C. and a boiling point of 2403° C. Bi and Ga are substantially inert with respect to the precursors and have low tendency to form inclusions or undesired phases during annealing of gallium arsenide precursors. Experiments have shown that each of Bi and Ga help to increase the grain size of polycrystalline gallium arsenide derived from organometallic precursors with pre-associated Ga—As bonds.

The processes of the present invention further involve providing one or more suitable flux agents before, during, or after formation of the precursor film and at least partially prior to annealing. In one mode of practice, the flux agent is applied onto the precursor film at a temperature that is lower than the annealing temperature. For example, a layer of one or more flux agents may be formed on the precursor film at a temperature in the range from −25° C. to 350° C., preferably 10° C. to 80° C., more preferably 10° C. to room temperature. The flux agent may be applied as a solid or liquid depending on the application temperature. In some modes of practice, the flux agent(s) may be applied in admixture as a solution or dispersion and then allowed to dry to form a flux agent film on the precursor film. In other modes of practice, the flux agent may be provided as fine particles that are distributed to form a layer of particles on the precursor film. In another mode of practice, vapor phase or sputtering deposition techniques are used to form a liquid or solid flux layer on the precursor film. An important aspect of these illustrative modes of practice is that the flux agent material is in direct contact with the precursor film during at least a portion of the annealing stage of the process.

The amount of flux agent to be provided can vary over a wide range. As one consideration, if too little is used, the desired mobility effect may not be realized as much as desired so that not as large an increase in grain size is observed as compared to using larger amounts of the flux agent. Using excessive amounts of flux agent may not offer additional benefits to using lesser amounts. Also, removing the excess flux agent after annealing may be more cumbersome. Balancing such concerns, it is desirable to use enough flux agent(s) such that a liquid film formed from the melted flux during the annealing stage covers at least a portion, preferably a majority of, more preferably substantially all of the underlying precursor film. Desirably, the liquid phase has a thickness effective to function as a barrier. In illustrative embodiments, enough flux agent is used such that the corresponding liquid phase has a thickness in the range from 10 nm to 2 mm, preferably 100 nm to 1 mm, more preferably 100 nm to 0.5 mm.

The processes of the present invention further involve annealing the precursor film in the presence of the flux agent(s). The film is annealed under conditions effective to convert at least a portion of the precursor into polycrystalline gallium arsenide. In the practice of the present invention, the annealing occurs in the presence of the liquid flux phase in contact with at least a portion of the film during at least a portion of the annealing. Annealing the precursor in the presence of a flux agent converts at least a portion of the precursor into polycrystalline material. Upon annealing, for example, organometallic gallium arsenide precursors according to Formula B and/or C yield polycrystalline gallium arsenide, preferably stoichiometric or substantially stoichiometric gallium arsenide. As an option, one or more dopants and/or alloy constituents may be incorporated into the polycrystalline Group III/Group V film before, during, and/or after annealing.

The precursor film used to form the polycrystalline Group III/Group V product may contain undesired constituents other than Ga and As, such as carbon, nitrogen, oxide, or other contamination. The thermal annealing process and/or a post annealing treatment may assist to drive out of the impurities and further purify the product. The thermal process may also help to repair defects. Annealing may also help to increase the density of the polycrystalline product.

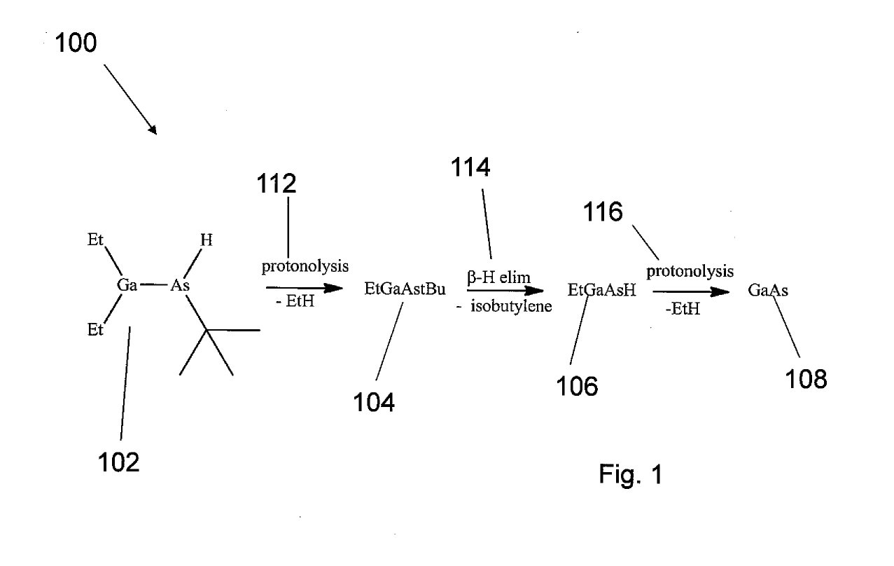

Annealing can occur at a wide variety of temperatures. If the temperature is too low, however, the crystallization may occur to slowly or may not occur at all. If the temperature is too high, then the desired stepwise loss of ligands may not occur correctly as described in FIG. 1, resulting in a significant remainder of carbonaceous material within the film. Generally, annealing at a temperature in the range from 400° C. to 650° C. would be suitable. Annealing desirably occurs in a protected atmosphere, such as argon, to minimize the risk of oxidation or moisture damage.

Annealing generally occurs for a time period sufficient to allow at least a portion, and more preferably substantially all of the precursor film to be converted into the polycrystalline pnictide product. If the time period is too short, the desired degree of reaction may not occur. Longer time periods may not provide additional benefit as compared to shorter time periods. Longer time periods also risk potential damage to temperature sensitive constituents of the substrate or precursor film. Balancing such concerns, annealing desirably occurs for a time period in the range from 30 seconds to 8 hours, preferably 2 minutes to 4 hours, more preferably 5 minutes to 2 hours. In one mode of practice, annealing at 600° C. for 15 minutes would be suitable.

In some embodiments, annealing occurs at a pressure below 1 atm. Without wishing to be bound, it is believed that using reduced pressures may help to reduce As loss. Annealing in a closed system may help to further prevent such losses and may even allow annealing to occur effectively at 1 atm or higher pressures.

After annealing, remaining flux agent material, if any, can be removed if desired. Alternatively, the flux agent may be left in place if it serves a functional purpose or if it can be modified or otherwise processed to serve a functional purpose. If removal is desired, this can occur by a wide variety of removal techniques such as etching, laser ablation, polishing, sublimation, cross-reaction with a secondary material, simple liquid flow off, combinations of these, or the like.

FIG. 1 shows an illustrative schematic reaction scheme 100 by which precursors 102 of the present invention are converted into polycrystalline products 108. For purposes of illustration, scheme 100 illustrates the thermolysis of [tBuAs(H)GaEt₂]₃ to provide stoichiometric polycrystalline gallium arsenide product 108. The organometallic precursor 102, organometallic precursor intermediate 104, and organometallic intermediate 106 are shown in scheme 100 as monomers, even though in actual practice precursor 102 is believed to be a trimer and each the intermediates (104 and 106) are believed to be more associated. In step 112, organometallic precursor 102 is provided at room temperature and then heated up to 600° C. Precursor 102 undergoes protonolysis and evolves ethane. Studying the thermolysis by evolved gas analysis, it was observed that the on-set of ethane evolution occurs below 50° C. Evolution of ethane via protonolysis yields intermediate 104. As annealing continues, intermediate 104 in step 114 undergoes β-H elimination to evolve isobutylene. This provides intermediate 106. As annealing continues, intermediate 106 undergoes protonolysis in step 116 to evolve ethane. The resultant product 108 is the desired polycrystalline, stoichiometric gallium arsenide.

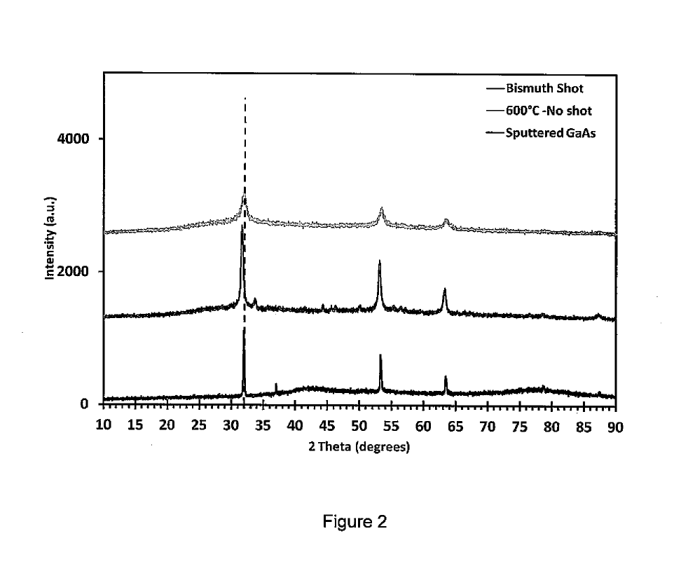

Interestingly, the onset of ethane formation in step 112 may occur even at room temperature as evidenced by the formation of cluster species having the formula {[tBuAs(H)GaEt₂]₃(tBuAsGaEt)₂}. This indicates that precursor embodiments according to Formula B have very favorable decomposition characteristics. Upon standing or long term storage, therefore, a precursor according to Formula B may decompose to form a corresponding precursor of Formula C. In the past, decomposition of a precursor has been viewed as undesirable. However, in the present scenario, decomposition of precursor 102 does not produce undesirable by-products, but rather results in intermediate 104 useful in the formation of polycrystalline gallium arsenide product 108. This is quite advantageous as precursor 102 is thus at least partially reacted to form intermediate 104 according to scheme 100 of FIG. 2. Upon annealing, the reaction proceeds even further from the same intermediate 104 to form the desired product 109. Since the precursor 102 forms the desired intermediate 104 during storage, the precursor 102 as a practical matter has a relatively long shelf life. In the practice of the present invention, this kind of decomposition need not be avoided and may even be highly desirable from the perspective that precursor 102 is at least partially reacted to get a head start on formation of product 108.

It may still be desirable to store precursor embodiments such as precursor 102 under conditions to minimize decomposition of Ga—As bonds and/or prevent early formation of gallium arsenide under conditions by which the crystalline characteristics are inferior to those resulting from high temperature annealing. Accordingly, if precursor embodiments such as precursor 102 are not going to be used very soon after its synthesis, it may be desirable to store such precursor embodiments in a protected storage vessel isolated from light, oxygen and moisture at cool temperatures, e.g., −50° C. to 0° C. until the time of use.

In addition to studying thermolysis of precursor 102 in the reaction scheme 100 shown in FIG. 1, the thermolysis of other organometallic gallium arsenide precursors also was studied. These other precursors were (Ph₂AsGaMe₂)₃, (Ph₂AsGaEt₂)₃, (tBu₂AsGaMe₂)₂, (tBu₂AsGaEt₂)₂, and (Et₂GaAsEt₂)_{b}, wherein b is 1 to 6 or more, or even 2 or 3. It was shown that each of the GaAs products formed from these other precursors were arsenic deficient as measured by energy-dispersive spectroscopy (EDS).

Moreover, the thermolysis of [tBuAs(H)GaMe₂]ₙ also was studied, wherein n is believed to be 3 based upon NMR analysis. Thermolysis of this precursor also did not provide stoichiometric polycrystalline GaAs. In addition, we did not observe the low temperature on-set of methane formation. The failure to evolve methane indicates that the desired protonolysis reaction did not occur as readily as in the ethyl analogue [tBuAs(H)GaEt₂]ₙ used in scheme 100 of FIG. 2. Recalling that the BDE of methyl is higher than that of ethyl with respect to Ga, this reinforces our hypothesis that compounds with stronger Ga—R₂ bonds are less suitable GaAs precursors when stoichiometric or substantially stoichiometric GaAs is a desired product. Therefore, to form stoichiometric or substantially stoichiometric GaAs, precursors with weaker ligand bonds to gallium provide a substantial synthesis advantage. The following table shows how precursor composition influences the GaAs stoichiometry:

| Precursor | Ga:As ratio following 600° C. Anneal |
|---|---|
| Et₂AsGaEt₂ | 94:6 |
| tBu₂AsGaMe₂ | 87:13 |
| tBu₂AsGaEt₂ | 66:33 |
| Ph₂AsGaMe₂ | 63:37 |
| Ph₂AsGaEt₂ | 73:27 |
| tBu(H)AsGaMe₂ | 78:22 |
| tBu(H)AsGaEt₂ | 50:50 |

The present invention will now be further described with reference to the following illustrative examples. The solvents were deoxygenated by purging with dry N₂ for 30 min and dried by passing down a column (40 cm) of activated alumina and molecular sieves (4 Å). The syntheses of organometallic precursors described in the Examples were undertaken in refluxing hexane using a stoichiometric amount of the trialkyl gallium at around 80° C. Under these conditions the hexane and trimethylgallium are volatile, and the work was in a closed system. The reactions were performed in 40 mL Chem Glass vials (CG-4912-06) that contained a pressure relief cap. The vials are capable of holding a pressure of about 6 atm before the relief cap bursts. During our experiments, none of the caps burst, and the calculated pressure was about 2 atmospheres.

### Example 1

### Synthesis of [tBu(H)AsGaMe₂]ₙ

A 40 mL vial was charged with tBuAsH₂ (134 mg, 1 mmol) and diluted with hexane (15 mL). To the vial, Me₃Ga (1 mmol, 115 mg) was added. The mixture was heated to about 70° C. for 24 h. The volatiles were removed under reduced pressure to afford a colorless solid Yield: 211 mg, 90.6%. ¹H NMR (400 MHz, C₆D₆, 25° C.): δ 2.37, (s, As—H, 0.22H), 2.25 (s, As—H, 0.42H), 2.08 (s, As—H, 0.22H), 1.30 (m, As-tBu, 9H), 0.36 (s, Ga-Me, 1.28H), 0.33 (s, Ga-Me, 1.15H), 0.31 (s, Ga-Me, 1.87H), 0.28 (s, Ga-Me, 0.71H). ¹³C NMR (101 MHz, C₆D₆, 25° C.): δ 35.75, 35.38, 35.07, 34.07, 33.77, 1.24, 0.45, −1.28, −1.59, −3.10, −3.29.

### Example 2

### Synthesis of [tBu(H)AsGaEt₂]ₙ

A 40 mL vial was charged with tBuAsH₂ (134 mg, 1 mmol) and diluted with hexane (15 mL). To the vial, Et₃Ga (1 mmol, 156 mg) was added. The mixture was heated to about 70° C. for 24 h. The volatiles were removed under reduced pressure to afford a colorless solid. Yield: 238 mg, 91.5%. ¹H NMR (400 MHz, C₆D₆, 25° C.): δ 2.39, (s, As—H, 0.27H), 2.30 (s, As—H, 0.52H), 2.17 (s, As—H, 0.14H), 1.43 (m, Ga—CH₂CH₃, 6H), 1.35 (m, As-tBu, 9H), 0.93 (M, Ga—CH₂CH₃, 4 H). ¹³C NMR (101 MHz, C₆D₆, 25° C. ¹³C NMR) 8 35.40, 35.11, 34.89, 34.36, 34.17, 12.67, 12.52, 12.30, 12.14, 11.81, 11.68, 9.15, 8.63, 8.24, 8.08, 7.38, 7.08.

### Example 3

### Synthesis of {[tBu(H)AsGaEt₂]₃(tBuAsGaEt)₂}

A 5 mL vial was charged with tBuHAsGaEt₂ (0.242 g, 0.9272 mmol) and dissolved in hexane (1 mL). The solution was stored in the dry box for 53 days and it was noticed that colorless crystals appeared. Yield (19%; 44 mg). The crystals were shown to be {[tBuAs(H)GaEt₂]₃(tBuAsGaEt)₂} by X-ray crystallography and NMR spectroscopy. ¹H NMR (400 MHz, C₆D₆, 25° C.): δ 2.9, (s, As—H, 1.03H), 2.87 (s, As—H, 1.00H), 2.55 (s, As—H, 1.05H), 1.50 (m, Ga—CH₂CH₃, 18H and As-tBu, 18H), 1.38-1.25 (m, Ga—CH₂CH₃, 6H), 1.38 (s, As-tBu, 9H), 1.35 (s, As-tBu, 9H), 1.27 (s, As-tBu, 9H), 1.25-0.95 (m, Ga—CH₂CH₃, 16 H).

### Example 4

### Synthesis of (Ph₂AsGaMe₂)₃

A 40 mL vial was charged with Ph₂AsH (230.1 mg, 1 mmol) diluted in hexane (15 mL). To the vial, Me₃Ga (3 mmol, 344.5 mg) was added. The mixture was stirred for 30 min, sealed, and heated to 60° C. for 48 h. A colorless precipitation formed after stirring for 30 min. The mixture was concentrated under reduced pressure to about 5 mL and the solid was collected. Yield: 341.2 g, 95.5% based on As. ¹H NMR (400 MHz, C₆D₆, 25° C.): δ 7.42 (m, 411), 6.97 (m, 2H), 6.93 (m, 4H), 0.37 (s, 6H). ¹³C NMR (101 MHz, C₆D₆, 25° C.): δ 135.24 (Ar—H), 134.58, 129.22 (Ar—H), 128.50, −5.25 (CH₃).

### Example 5

### Synthesis of (Ph₂AsGaEt₂)₃

A 40 mL vial was charged with Ph₂AsH (230.1 mg, 1 mmol) diluted in hexane (15 mL). To the vial, Et₃Ga (3 mmol, 470 mg) was added. The mixture was stirred for 30 min, sealed, and heated to 60° C. for 48 h. The reaction was concentrated to about 4 mL and a colorless precipitate formed. The mixture was heated to 60° C. and the precipitate dissolved. Upon cooling to room temperature X-ray quality crystals formed. Yield: 0.361 g, 93.7% based on As. ¹H NMR (400 MHz, C₆D₆, 25° C.): δ 7.51 (m, 4H), 6.98 (m, 6H), 1.23 (t, J=7.6 Hz, 6H), 1.14 (q, J=7.6 Hz, 4H). ¹³C NMR (101 MHz, C₆D₆, 25° C.): δ 135.39 (Ar—H), 135.29, 129.06 (Ar—H), 128.44, 12.19 (CH₂CH₃), 6.58 (CH₂CH₃) (s).

### Example 6

### Synthesis of (tBu₂AsGaMe₂)₂

A 40 mL vial was charged with tBu₂AsH (189.9 mg, 1 mmol) diluted in hexane (15 mL) and Me₃Ga (3 mmol, 344.5 mg) was added. The mixture was stirred for 30 min and then sealed and heated to 60° C. for 18 h. The solvent was removed under reduced pressure along with the excess Me₃Ga to afford a colorless solid. Yield: 0.252 g, 87.6% based on As. ¹H NMR (400 MHz, C₆D₆, 25° C.): δ 0.39 (s, 6H, Me), 1.39 (s, 18H, C(CH₃)₃). ¹³C NMR (101 MHz, C₆D₆, 25° C.): δ 0.73 (Me), 33.16 [C(CH₃)₃], 39.96 [C(CH₃)₃].

### Example 7

### Synthesis of (tBu₂AsGaEt₂)₂

A 40 mL vial was charged with tBu₂AsH (189.9 mg, 1 mmol), diluted with hexane (15 mL), and GaEt₃ (3 mmol, 470 mg) was added. The mixture was stirred for 30 min, sealed, and heated to 60° C. for 18 h. The solvent was removed under reduced pressure along with the excess Et₃Ga. Yield: 0.289 g, 91.5% based on As. ¹H NMR (400 MHz, C₆D₆, 25° C.): δ 1.43 (t, J=7.9 Hz, 6H, CH₂CH₃), 1.40 (s, 9H, C(CH₃)₃), 1.05 (q, J=7.9 Hz, 4H, CH₂CH₃). ¹³C NMR (101 MHz, C₆D₆, 25° C.): δ 39.41 [C(CH₃)₃], 33.36 [C(CH₃)₃], 11.24 (CH₂CH₃), 8.33 (CH₂CH₃).

### Example 8

### Synthesis of (Et₂AsGaEt₂)ₙ

Et₂AsH (133.9 mg, 1 mmol) was diluted in hexane (15 mL) and GaEt₃ (3 mmol, 470 mg) was added. The reaction vessel was a 40 mL vial with a stir bar. It was stirred for 30 min and then sealed and heated to 60° C. for 48 h. The solvent was removed under reduced pressure along with the excess Et₃Ga. Yield: 0.235 g, 90.2% based on As. ¹H NMR. (400 MHz, C₆D₆, 25° C.) δ 1.75 (q, J=7.7 Hz, 4H), 1.39 (t, J=7.7 Hz, 6H), 1.16 (t, J=7.7 Hz, 6H), 0.81 (q, J=7.7 Hz, 4H), ¹³C NMR (101 MHz, C₆D₆, 25° C.): δ 13.21 (As—CH₂CH₃), 12.56 (As—CH₂CH₃), 11.02 (Ga—CH₂CH₃), 5.29 (Ga—CH₂CH₃).

### Example 9

### Thermolysis Studies

Thin films were prepared by drop-casting about 40 μl of solutions of each precursor shown in the following table (0.8 M in toluene) onto a piece of pre-cleaned and pre-weighed piece of borosilicate glass. The coated samples were allowed to dry overnight within a glovebox in a protected atmosphere of argon. Each sample was then annealed at 600° C. for 15 minutes. Annealing occurred in a quartz tube oven set up inside of an argon-atmosphere glovebox. The flow rate of argon inside the tube was set to 60 SCCM. The pressure inside the tube was controlled via a back pressure regulator set to two psi. All loading and unloading operations were performed in the glovebox to minimize sample oxidation. Following sample loading into the quartz tube oven, the tube environment was allowed to equilibrate to two psi prior to heating. After annealing, the stoichiometry of the gallium arsenide product was assessed using SEM-EDS analysis. The results are shown in the following table.

TABLE 9A
Table showing the influence of precursor composition on the
stoichiometry of the resulting GaAs material.

| Precursor | Ga:As ratio following 600° C. Anneal |
|---|---|
| (Et₂AsGaEt₂)ₙ | 94:6 |
| (tBu₂AsGaMe₂)₂ | 87:13 |
| (tBu₂AsGaEt₂)₂ | 66:33 |
| (Ph₂AsGaMe₂)₃ | 63:37 |
| (Ph₂AsGaEt₂)₃ | 73:27 |
| (tBu(H)AsGaMe₂)ₙ | 78:22 |
| (tBu(H)AsGaEt₂)ₙ | 50:50 |

The data shows that thermolysis of the precursors provided the most stoichiometric polycrystalline gallium arsenide when the As included an H ligand and an organic ligand, and the ligands on the Ga had 2 or more carbon atoms.

### Example 10

### Anneal of thin films of (tBut(H)AsGaEt₂)ₙ

In a specific example for the formation of polycrystalline GaAs from (tBut(H)AsGaEt₂)ₙ, thin films were prepared by drop-casting about 40 μl of (tBut(H)AsGaEt₂)ₙ (0.8 M in toluene) onto a piece of pre-cleaned and pre-weighed piece of borosilicate glass. The samples were allowed to dry overnight at room temperature (˜23° C.) within a glovebox in a protected atmosphere of argon. Annealing occurred in an inert atmosphere in a quartz tube oven that was set up inside of an argon-atmosphere glovebox. The glovebox O₂ level was maintained below two parts-per-million (ppm) to ensure a stable moisture-free and O₂-free environment. The gas flow was controlled using a manual flow controller, set to 60 SCCM. The pressure inside the tube was controlled via a back pressure regulator set to two psi. The thin films were annealed in the oven for 15 minutes at a temperature of 600° C. The key output variables monitored in the experiments were the total mass loss, material stoichiometry, and the crystalline size for any potentially formed GaAs. Following the anneal a 55:45 Ga:As atomic ratio was observed with a 58% overall yield based on mass. The average crystalline size of the GaAs grains was determined by X-ray diffraction methods utilizing the Scherrer equation to be 12 nm.

### Example 11

### Anneal of Thin Films with Bi as Flux Agent

A (tBut(H)AsGaEt₂)ₙ precursor was drop-cast onto a glass substrate and allowed to dry to a solid state. The film was covered with a layer of Bismuth (Bi) granules, and heated to the final process temperature of 600° C. for a period of 15 minutes and annealed as described in Example 10. The melting point of Bi is 272° C. Following the anneal, the Bi granules were removed utilizing tweezers. The remaining thin film was analyzed by X-ray diffraction methods and SEM-EDS analysis. The crystalline grain size was estimated by the use of Scherrer analysis to be approximately 30 μm Annealing the same material under the same conditions in the absence of a Bi flux agent resulted in crystalline size of approximately 12 nm, as described in Example 10. SEM-EDS analysis demonstrated the formation of a homogeneous GaAs phase with a 51:49 atomic ratio of Ga:As.

FIG. 2 shows an XRD plot showing the impact of Bi on the crystallization of (tBu(H)AsGaEt₂)ₙ. The increase in peak height and decrease in peak width can be correlated to the increase in crystalline grain size by the Scherrer equation.

### Example 12

### Anneal of Thin Films with Ga as Flux Agent

A (tBut(H)AsGaEt₂)ₙ precursor was drop-cast onto a glass substrate and allowed to dry to a solid state. The film was covered with a layer of Gallium (Ga) granules, and heated to the final process temperature of 600° C. and annealed as described in Example 10. The melting point of Ga is 29.7° C. Following the anneal, the Ga metal granules were removed utilizing tweezers. However, some metal clearly remained on the surface. The remaining thin film was analyzed by X-ray diffraction methods and SEM-EDS analysis. The crystalline grain size was estimated by the use of Scherrer analysis, to be approximately 85 nm. EDS analysis showed a large excess of Ga on the sample, likely owing to unremoved Ga metal.

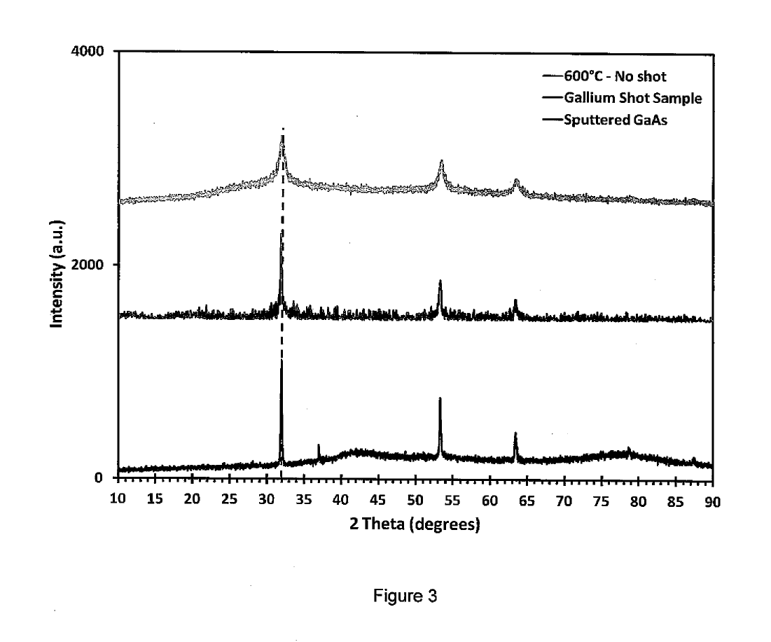

FIG. 3 shows an XRD plot showing the impact of Ga on the crystallization of tBu(H)AsGaEt₂. The increase in peak height and decrease in peak width can be correlated to the increase in crystalline grain size by the Scherrer equation.

The foregoing detailed description has been given for clarity of understanding only. No unnecessary limitations are to be understood therefrom. The invention is not limited to the exact details shown and described, for variations obvious to one skilled in the art will be included within the invention defined by the claims.

What is claimed is:

1. A method of making polycrystalline gallium arsenide, comprising the steps of:
a) providing at least one single source organometallic precursor comprising at least one Group III-Group V bond;
b) using the precursor to form a precursor film comprising at least the single source organometallic precursor; and
c) annealing the precursor film in the presence of a liquid phase in physical contact with at least a portion of the precursor film during at least a portion of the annealing, wherein the annealing occurs under conditions effective to convert at least a portion of the single source organometallic precursor into a polycrystalline Group III-Group V compound.

2. The method of claim 1, wherein the polycrystalline Group III-Group V compound has the formula
MₓGa_{y}AsₙP^{N}ₘ
wherein M is one or more metals other than Ga; P^{N} is one or more pnictogens other than As; x+y=1; n+=1, x is 0 to 0.3; y is 0.7 to 1.0; n is 0.7 to 1.0 and m is 0 to 0.3.

3. The method of claim 1, wherein the polycrystalline Group III-Group V compound is a stoichiometric, polycrystalline GaAs semiconductor compound.

4. The method of claim 1, wherein at least one single source organometallic precursor have Formula B
[R¹HAs—GaR³₂]ₚ
and/or Formula C:
[R¹As—GaR³]_{q}
wherein each R¹ independently is H or an organic moiety comprising 2 to 10 carbon atoms and R³ independently is an organic moiety comprising 2 to 10 carbon atoms; p is 1 to 6; and q is 1 to 8.

5. The method of claim 4, wherein R¹ is selected from ethyl, t-butyl, and combinations thereof.

6. The method of claim 4, wherein R² is selected from ethyl, t-butyl, and combinations thereof.

7. The method of claim 4, wherein p is 3 and/or q is 2.

8. The method of claim 4, wherein R¹ is t-butyl and R² is ethyl.

9. The method of claim 1, wherein the at least one precursor comprises at least one cluster species selected from one or more of
{[tBu(H)AsGaEt₂]ₘ(tBuAsGaEt)ₙ};
{[tBu(H)AsGa(CH₂Ph)]ₘ[tBuAsGa(CH₂Ph)]ₙ};
{[tBu(H)AsGa(tBu₂)]ₘ[tBuAsGa(tBu)]ₙ};
{[Et(H)AsGaEt₂]ₘ[(EtAsGaEt)]ₙ};
{[Et(H)AsGa(CH₂Ph)]ₘ[(EtAsGa(CH₂Ph)]ₙ};
{[Et(H)AsGa(tBu₂)]ₘ[(EtAsGa(tBu)]ₙ};
{[(CH₂Ph)(H)AsGaEt₂]ₘ[(CH₂Ph)AsGaEt)]ₙ};
{[(CH₂Ph)(H)AsGa(tBu)]ₘ[(CH₂Ph)AsGa(tBu)]ₙ};
{[CH₂Ph)(H)AsGa(CH₂Ph)]ₘ[(CH₂Ph)AsGa(CH₂Ph)]ₙ};
{[tBu(H)AsGaEt₂]ₘ(tBuAsGatBu)ₙ};
{[tBu(H)AsGatBu₂]ₘ(tBuAsGaEt)ₙ};
{[tBu(H)AsGatBu₂]ₘ(tBuAsGatBu)ₙ};
{[tBu(H)AsGaEt₂]ₘ(tBuAsGa(CH₂Ph))ₙ};
{[tBu(H)AsGa(CH₂Ph)₂]ₘ(tBuAsGaEt)ₙ}; and/or
{[tBu(H)AsGa(CH₂Ph)₂]ₘ(tBuAsGa(CH₂Ph))ₙ};
wherein each m and n independently is 1 to 10.

10. The method of claim 1, wherein the at least one precursor comprises at least one cluster species.

11. The method of claim 1, wherein the liquid phase comprises liquid Bi.

12. The method of claim 1, wherein the liquid phase comprises liquid Ga.

13. The method of claim 1, wherein the liquid phase comprises at least one constituent having a melting point below 400° C. and a boiling point above 1000° C. as measured at 1 atm of pressure.

14. The method of claim 1, wherein annealing occurs in a temperature range from 400° C. to 650° C.

15. A Group III-Group V precursor system, comprising:
a) a single source organometallic precursor film comprising at least one organometallic precursor comprising a Group III-Group V bond; and
b) a flux layer in physical contact with and at least partially covering the precursor film, wherein the flux layer comprises at least one constituent that has a boiling point greater than 650° C. at 1 atm of pressure and wherein the constituent exists in a liquid phase in contact with the organometallic precursor film at a temperature in the range from 400° C. to 650° C. at 1 atm of pressure.
